(19) United States
(12) Patent Application Publication
(10) Pub. No.: US 2022/0165893 A1
(43) Pub. Date: May 26, 2022

(54) Photodetectors Having Optical Grating Couplers Integrated Therein and Related Methods

(71) Applicant: SWIR Vision Systems Inc., Durham, NC (US)

(72) Inventors: Sean Hinds, Ottawa (CA); Ethan J.D. Klem, Chapel Hill, NC (US); Christopher William Gregory, Chapel Hill, NC (US); Jeffery Allan Hilton, JR., Durham, NC (US); Greg Alan Hames, Raleigh, NC (US)

(21) Appl. No.: 17/532,299

(22) Filed: Nov. 22, 2021

Related U.S. Application Data
(60) Provisional application No. 63/117,548, filed on Nov. 24, 2020.

(51) Int. Cl. H01L 31/0232; H01L 31/0352; H01L 31/101; G02B 5/18

(52) U.S. Cl. CPC H01L 31/02327; G02B 5/1819; H01L 31/101; H01L 31/035218

(57) ABSTRACT

An integrated device is provided including a substrate; a CQD photodetector on the substrate; and an integrated optical grating contact on the substrate. The integrated optical grating contact is a conductive grating contact and is provided between the substrate and the photodetector. The integrated device further includes a top contact on the photodetector.

### CLAIM OF PRIORITY

The present application claims priority to U.S. Provisional Application No. 63/117,548, filed on Nov. 24, 2020 entitled Optical Grating Couplers for Colloidal Quantum Dot Photodetectors, the content of which is hereby incorporated herein by reference as if set forth in its entirety.

### FIELD

The present inventive concept relates generally to optical grating couplers and colloidal quantum dot photodetectors, more particularly, to grating couplers integrated into the structure of colloidal quantum photodetectors for the purpose of increasing the optical path length and optical absorption inside colloidal quantum dot photodetectors.

### BACKGROUND

Focal-plane arrays (FPAs) are image sensing devices consisting of an array of light-sensing pixels at the focal plane of a lens. FPAs are used most commonly for imaging purposes, for example, taking pictures or video imagery, but can also be used for non-imaging purposes, such as spectrometry, light detection and ranging (LIDAR), and wave-front sensing.

At visible and infrared wavelengths FPA can refer to a variety of imaging device types, but in common usage it refers to two-dimensional devices that are sensitive in the infrared spectrum. Devices sensitive in other spectra are usually referred to by other terms, such as CCD (charge-coupled device) and CMOS image sensor in the visible spectrum. FPAs operate by detecting photons at particular wavelengths and then generating an electrical charge, voltage, or resistance in relation to the number of photons detected at each pixel. This charge, voltage, or resistance is then measured, digitized, and used to construct an image of the object, scene, or phenomenon that emitted the photons. There are two basic types of focal plane arrays: linear and area. Linear focal plane arrays consist of a single line of pixels. Area focal plane arrays consist of rows and columns of pixels.

Colloidal quantum dot (CQD) photodetectors are photodetectors that use thin films composed of an ensemble of small particles of semiconductor material to absorb photons and detect light. Grating couplers are a commonly used optical element and can be used in integrated optics for coupling light into and out of locations on a chip. Grating couplers have been previously used in infrared-sensitive FPAs made from Quantum Well Infrared Photodetectors (QWIP). They enable imaging in QWIP devices by coupling normal-incident light into the quantum well structure which would otherwise be unable to effectively absorb the normal-incident photons found in imaging systems.

### SUMMARY

Some embodiments of the present inventive concept provide a non-quantum well infrared photodetector (QWIP) device including an integrated optical grating coupler therein.

In further embodiments, the integrated optical grating coupler may be positioned on a top surface of the device, a bottom surface of the device or in between the top surface and the bottom surface of the device in a middle portion of the device.

In still further embodiments, the optical grating coupler may include a conductive material.

In some embodiments, the optical grating coupler may include metal.

In further embodiments, the metal optical grating coupler may include a patterned array of posts.

In still further embodiments, a shape of the integrated optical grating coupler may be periodic, random, post shaped, pillar shaped, contains holes, includes grids, and/or includes recessed grids.

In some embodiments, the non-QWIP device comprises a colloidal quantum dot (CQD) photodetector device.

In further embodiments, the device including the integrated optical grating coupler may have an increased optical quantum efficiency without increasing dark noise relative to devices without integrated optical couplers.

In still further embodiments, the quantum efficiency may increase in devices having an integrated optical coupler by at least fifty percent.

In some embodiments, the integrated optical grating coupler is for use with short wavelengths from about 1000 nm to about 3000 am.

In further embodiments, the device may include non-QWIP materials that couple light at normal incidence.

In still further embodiments, the non-QWIP materials may include at least one of InGaAs, Si and CQD.

Some embodiments of the present inventive concept provide an integrated device including a substrate; a CQD photodetector on the substrate; and an integrated optical grating contact on the substrate.

In further embodiments, the integrated optical grating contact may be a conductive grating contact and may be provided between the substrate and the photodetector. The integrated device may further include a top contact on the photodetector.

In still further embodiments, the conductive grating contact may be patterned to provide one of a periodic pattern and a random pattern.

In some embodiments, the conductive grating contact may include a patterned array of posts.

In further embodiments, the device may be a non-QWIP device.

In still further embodiments, the device may include non-QWIP materials that couple light at normal incidence.

In some embodiments, the non-QWIP materials may include at least one of InGaAs, Si and CQD.

In further embodiments, presence of the integrated optical grating contact may increase optical path length and optical absorption inside the photodetector.

### BRIEF DESCRIPTION OF THE DRAWINGS

FIGS. 1A and 1B are diagrams illustrating a random and coherent grating coupler, respectively, for quantum well infrared photodetectors (QWIPs).

FIGS. 2A and 2B is a diagrams illustrating a cross section of a Focal-plane array (FPA) grating coupler for use with non-QWIP photodetectors and a top view showing the posts, respectively, in accordance with some embodiments of the present inventive concept.

FIGS. 3A through 3C are scanning electron microscope (SEM) images of examples of optical grating couplers used to build Colloidal quantum dot (CQD) photodetectors in accordance with some embodiments of the present inventive concept.

FIG. 4 is an image illustrating spectral quantum efficiency comparing the performance of CQD photodetectors fabricated with integrated optical grating couplers and without an optical grating coupler in accordance with some embodiments of the present inventive concept.

FIG. 5 is a graph illustrating external quantum efficiency (EQE) versus wavelength (nm) for a plurality of different optical grating structures in accordance with some embodiments of the present inventive concept.

FIG. 6 is a graph illustrating EQE versus wavelength (nm) for a plurality of different QE structures in accordance with some embodiments of the present inventive concept.

FIGS. 7A an 7B are cross sections illustrating processing steps in the fabrication of devices in accordance with some embodiments of the present inventive concept.

### DETAILED DESCRIPTION

The present inventive concept will be described more fully hereinafter with reference to the accompanying figures, in which embodiments of the inventive concept are shown. This inventive concept may, however, be embodied in many alternate forms and should not be construed as limited to the embodiments set forth herein.

Accordingly, while the inventive concept is susceptible to various modifications and alternative forms, specific embodiments thereof are shown by way of example in the drawings and will herein be described in detail. It should be understood, however, that there is no intent to limit the inventive concept to the particular forms disclosed, but on the contrary, the inventive concept is to cover all modifications, equivalents, and alternatives falling within the spirit and scope of the inventive concept as defined by the claims. Like numbers refer to like elements throughout the description of the figures.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof. Moreover, when an element is referred to as being “responsive” or “connected” to another element, it can be directly responsive or connected to the other element, or intervening elements may be present. In contrast, when an element is referred to as being “directly responsive” or “directly connected” to another element, there are no intervening elements present. As used herein the term “and/or” includes any and all combinations of one or more of the associated listed items and may be abbreviated as “/”.

Unless otherwise defined, all terms (including technical and scientific terms) used herein have the same meaning as commonly understood by one of ordinary skill in the art to which this inventive concept belongs. It will be further understood that terms used herein should be interpreted as having a meaning that is consistent with their meaning in the context of this specification and the relevant art and will not be interpreted in an idealized or overly formal sense unless expressly so defined herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure. Although some of the diagrams include arrows on communication paths to show a primary direction of communication, it is to be understood that communication may occur in the opposite direction to the depicted arrows.

As used herein, the term “optoelectronic device” generally refers to any device that acts as an optical-to-electrical transducer or an electrical-to-optical transducer. Accordingly, the term “optoelectronic device” may refer to, for example, a photovoltaic (PV) device (for example, a solar cell), a photodetector, a thermovoltaic cell, or electroluminescent (EL) devices such as light-emitting diodes (LEDs) and laser diodes (LDs). In a general sense, EL devices operate in the reverse of PV and photodetector devices. Electrons and holes are injected into the semiconductor region from the respective electrodes under the influence of an applied bias voltage. One of the semiconductor layers is selected for its light-emitting properties rather than light-absorbing properties. Radiative recombination of the injected electrons and holes causes the light emission in this layer. Many of the same types of materials employed in PV and photodetector devices may likewise be employed in EL devices, although layer thicknesses and other parameters must be adapted to achieve the different goal of the EL device.

As used herein, the term “quantum dot” or “QD” refers to a semiconductor nanocrystal material in which excitons are confined in all three spatial dimensions, as distinguished from quantum wires (quantum confinement in only two dimensions), quantum wells (quantum confinement in only one dimension), and bulk semiconductors (unconfined). Also, many optical, electrical and chemical properties of the quantum dot may be strongly dependent on its size, and hence such properties may be modified or tuned by controlling its size. A quantum dot may generally be characterized as a particle, the shape of which may be spheroidal, ellipsoidal, or other shape. The “size” of the quantum dot may refer to a dimension characteristic of its shape or an approximation of its shape, and thus may be a diameter, a major axis, a predominant length, etc. The size of a quantum dot is on the order of nanometers, i.e., generally ranging from 1.0-1000 nm, but more typically ranging from 1.0-100 nm, 1.0-20 nm or 1-10 nm. In a plurality or ensemble of quantum dots, the quantum dots may be characterized as having an average size. The size distribution of a plurality of quantum dots may or may not be monodisperse. The quantum dot may have a core-shell configuration, in which the core and the surrounding shell may have distinct compositions. The quantum dot may also include ligands attached to its outer surface or may be functionalized with other chemical moieties for a specific purpose.

Plasma synthesis has evolved to be one of the most popular gas-phase approaches for the production of quantum dots, especially those with covalent bonds. For example, silicon (Si) and germanium (Ge) quantum dots have been synthesized by using nonthermal plasma. The size, shape, surface and composition of quantum dots can all be controlled in nonthermal plasma. Doping that seems quite challenging for quantum dots has also been realized in plasma synthesis. Quantum dots synthesized by plasma are usually in the form of powder, for which surface modification may be carried out. This can lead to excellent dispersion of quantum dots in either organic solvents or water, i.e., colloidal quantum dots (CQD). Solution synthesis of colloidal quantum dots is also a common method for producing these materials. In this approach, a solution-based synthetic method using organic solvents and soluble inorganic precursors is used to produce a paint-like suspension of CQD materials characterized by a particular CQD composition and size distribution. This suspension is then used to produce CQD films by through deposition processes, such as spin coating or spray coating that remove the CQD solvent, leaving a solid film of CQD material. Embodiments of the present inventive concept use CQD films as discussed below.

For purposes of the present disclosure, the spectral ranges or bands of electromagnetic radiation are generally taken as follows, with the understanding that adjacent spectral ranges or bands may be considered to overlap with each other to some degree: ultra-violate (UV) radiation may be considered as falling within the range of about 10-400 nm, although in practical applications (above vacuum) the range is about 200-400 nm. Visible radiation may be considered as falling within the range of about 380-760 nm. Infrared (IR) radiation may be considered as falling within the range of about 750-100,000 nm. IR radiation may also be considered in terms of sub-ranges, examples of which are as follows. Short wave infrared (SWIR) radiation may be considered as falling within the range of about 1,000-3,000 nm. Medium wave infrared (MWIR) radiation may be considered as falling within the range of about 3,000-5,000 nm. Long range infrared (LWIR) radiation may be considered as falling within the range of about 8,000-12,000 nm.

As discussed below, quantum dot photodiode (QDP) technology is implemented to provide low-cost nanotechnology-enabled photodetectors. In some implementations, the photodetectors may be configured to efficiently detect light with sensitivity spanning a spectral region ranging from about 250-2400 nm. Thus, the photodetectors may be configured as a multispectral device capable of producing images from incident ultraviolet (UV), visible and/or infrared (IR) electromagnetic radiation. In some implementations, the spectral range of sensitivity may extend down to X-ray energies and/or up to IR wavelengths longer than 2400 nm. The photodetectors as taught herein are cost effective, scalable to large-area arrays, and applicable to flexible substrates.

As used herein, “quantum efficiency” (QE) refers to the ratio of incident photons to measured electrons, with the optimal efficiency being 100%. In the case of Quantum well infrared photodetectors (QWIPs), absorption takes place only if the electric field vector of the radiation has a component perpendicular to the QW layer planes, which necessitates the angle of incidence with respect to these planes being different from zero. In the case of CQD detectors, optical absorption does not have this same perpendicular electric field vector requirement and instead occurs for any polarization or orientation of a photon's electric field vector.

“Dark current” refers to the residual electric current flowing in a photoelectric device when there is no incident illumination. In physics and in electronic engineering, dark current is the relatively small electric current that flows through photosensitive devices such as a photomultiplier tube, photodiode, or charge-coupled device even when no photons are entering the device. The dark current generally consists of the charges generated in the detector when no outside radiation is entering the detector. It can be referred to as reverse bias leakage current in non-optical devices and is present in all diodes. Physically, on source dark current is due to the random generation of electrons and holes within the depletion region of the device.

Quantum well infrared photodetectors (QWIPs) are infrared photodetectors that use electronic intersubband transitions in quantum wells to absorb photons. In other words, unlike photovoltaic (PV) or photoconductive (PC) detectors that rely on interband (valence band to conduction band) absorption in semiconductors, QWIPs rely on intersubband absorption of light between quantized energy states in quantum wells within the conduction/valence band.

As discussed above, Focal-plane array (FPA) grating couplers have previously been developed for use with QWIPs. The FPA grating couplers were specifically designed for QWIPs to permit imaging due to the inability, through quantum selection rules, to couple light into QWIPs at normal incident angles. As used herein, “normal” refers to light that intersects a surface at a right angle or substantially close to a right angle (90 degrees).

QWIP FPA grating couplers have been developed for use in the mid-infrared to far-infrared wavelength, but have not been developed for use in shorter wavelengths. Lack of development of the FPA grating couplers for the shorter wavelengths may be due to inherent physics constraints in the material of the QWIP itself, which may limit design to the mid-Infrared and beyond, i.e. greater than 3.5 microns. Furthermore, non-QWIP materials, such as Indium Gallium Arsenide (InGaAs), silicon (Si) and the like, generally do not require use of a grating coupler because these materials absorb light more efficiently through a lens and at normal incidence, unlike the QWIP materials as discussed above.

There is a fundamental trade-off for photodetector sensor materials between dark current and QE in direct relation to the thickness of the photodetector material. In particular, changing a thickness of the material, i.e. making the material thicker or thinner, improves one attribute at the expense of the other. Accordingly, some embodiments of the present inventive concept provide a grating coupler for use with non-QWIP FPA (photosensor) materials that improve the tradeoff between QE and dark current and provide a photosensor that optimized both QE and dark current. As used herein, non-QWIP photosensor materials refer to materials that couple light at normal incidence. These non-QWIP photosensor materials may include, for example, InGaAs, Si, CQDs, and the like.

Embodiments of the present inventive concept may provide low-light imagers having a decreased dark current without sacrificing QE. Similarly, colloidal quantum dot (CQD) film photodetectors may be provided with increased QE, without sacrificing dark current. With respect to CQD film photodetectors, making thicker sensors has proven a difficult challenge beyond hundreds of nanometer thicknesses. CQD photodetectors are discussed in, for example, commonly assigned U.S. patent application Ser. No. 17/199,971 (Attorney Docket No. 190823-00008) filed on Mar. 12, 2021 entitled Colloidal Quantum Dot (CQD) Photodetectors and Related Devices; U.S. Pat. No. 8,729,528 entitled Quantum Dot-Fullerene Junction Optoelectronic Devices; and U.S. Pat. No. 8,742,398 entitled Quantum Dot-Fullerene Junction Based Photodetectors, the contents of which are hereby incorporated herein by reference as if set forth in its entirety. However, it will be understood that embodiments of the present inventive concept are not limited to this configuration.

To address the tradeoff between QE and dark current, conventional devices have employed the use of anti-reflective coating resonant structures, anti-reflective coating with back reflector structures, and waveguide structures. However, improved methods are desired. FPA grating couplers in accordance with some embodiments discussed herein provide an enhancement to the dark current and quantum efficiency trade-off that is superior to that found in conventional devices by providing improved light coupling into the non-QWIP FPA sensor material. An example of a non-QWIP FPA material are CQD materials.

FPA grating couplers in accordance with embodiments discussed herein may be used in any device that may benefit from an improved relationship between QE and dark current. For example, embodiments of the present inventive concept may be used in applications that benefit from imaging with better signal to noise ratio (SNR) directly resulting from better QE or dark current performance as needed.

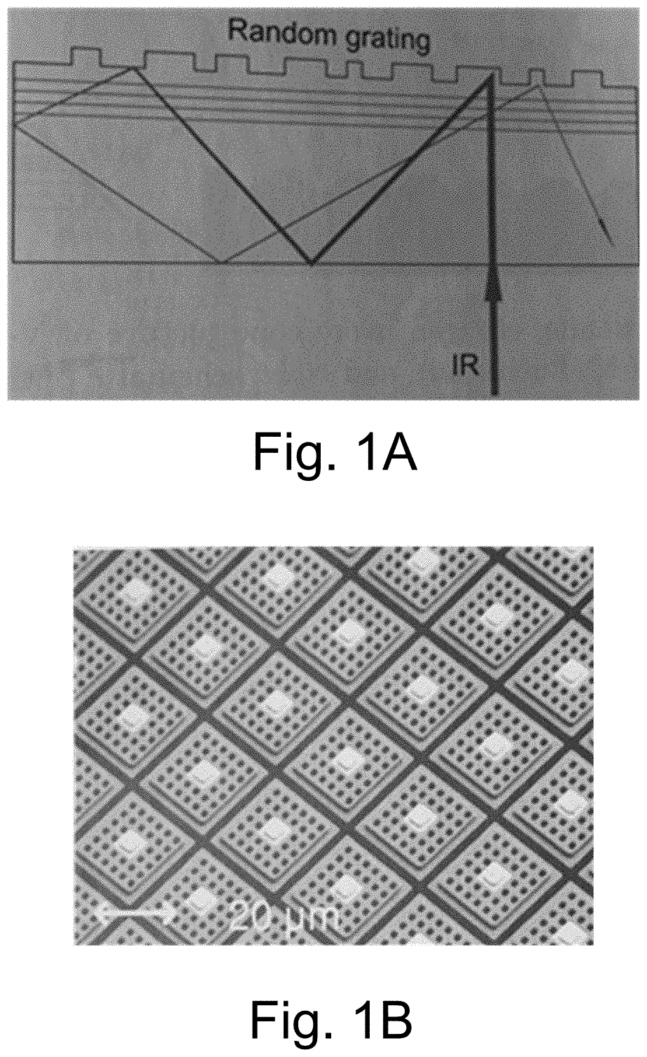

Referring to FIGS. 1A and 1B, a grating in accordance with embodiments of the present inventive concept can be random (FIG. 1A) or periodic (FIG. 1B) and can be designed to provide an enhanced optical coupling efficiency at a specific wavelength or range of wavelengths.

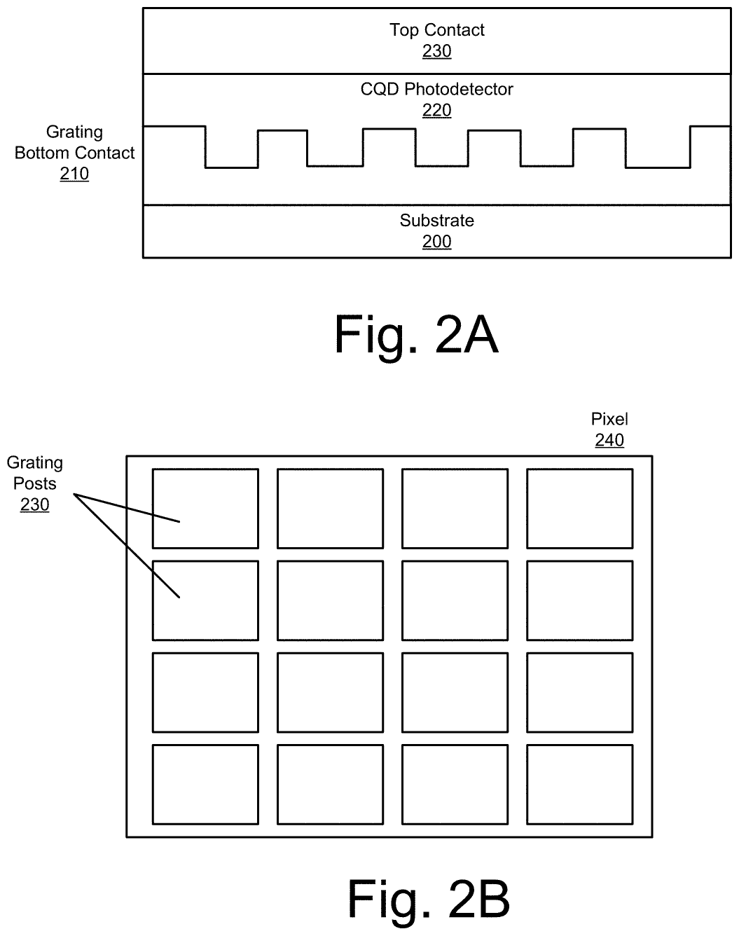

Referring now to FIGS. 2A and 2B, an example FPA grating coupler for use with non-QWIP photodetectors will now be discussed. For the device illustrated in FIG. 2A, a periodic grating structure is fabricated as part of a CQD photodetector device. The CQD device utilizes a conductive contact (grating bottom contact 210), such as a metal layer, as part of the diode layer stack. It will be understood that although the contact 210 is discussed as being metal, embodiments of the present inventive concept are not limited thereto. Other conductive materials may be used without departing from the scope of the present inventive concept. The conductive contact 210 is provided on a substrate 200. This conductive contact 210 may be fabricated to include a patterned array of posts 230 (FIG. 2B) illustrated in cross-section in FIG. 2A. The remaining layers of materials that are used to form a complete detector may be provided, for example, deposited, on the patterned conductive contact 210 as illustrated in FIG. 2A. For example, in FIG. 2A, a CQD photodetector 220 is provided on the conductive contact 210 and a top contact 230 is provided on the CQD photodetector 220. It will be understood as used herein, a “photodetector” refers to either a photoconductor, i.e. a conductor/resistor that changes in response to light, or a photodiode, i.e. a diode that change in response to light. The completed structure is a photodetector with an integrated optical grating. The optical properties of the grating may be determined by the physical dimensions of the periodic structure and the optical properties of the other layers in the diode stack. These optical properties include, for example, the index of refraction, absorption coefficient, thickness of the layers, shape and pitch of the grating structure. Examples of one such structure show the grating posts 230 and pixel 240 illustrated in FIG. 2B.

As used herein, the substrate 200 may be, for example, Si, Glass, Polymer, Ceramic, or metal material, or any combination thereof. In some embodiments, the substrate may be determined from the specific application requirements. For example, in an FPA, the substrate would typically be a Si wafer containing complementary metal-oxide semiconductor (CMOS) circuitry.

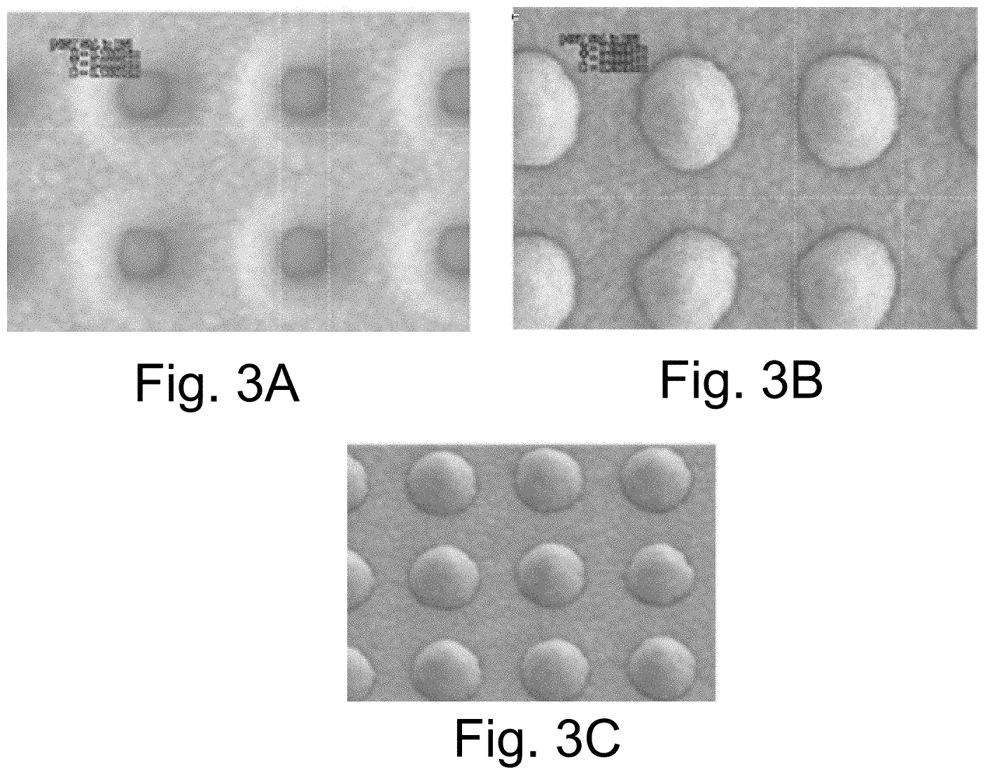

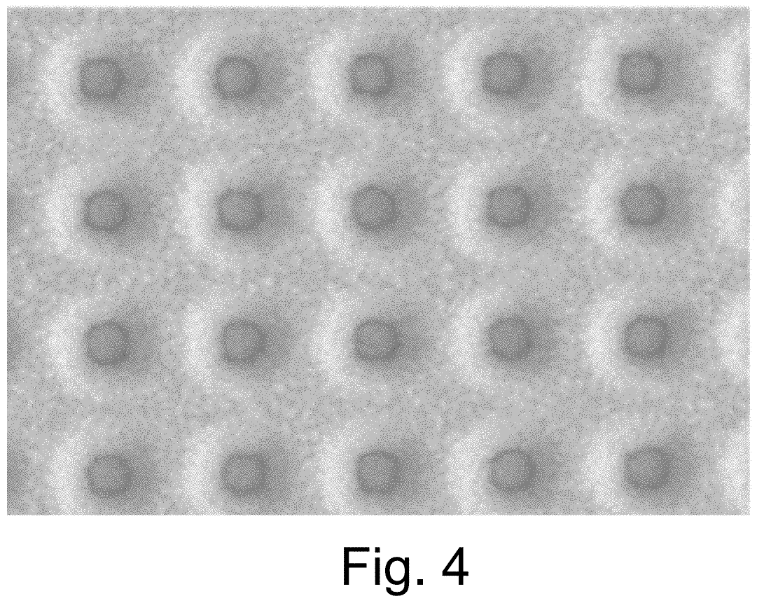

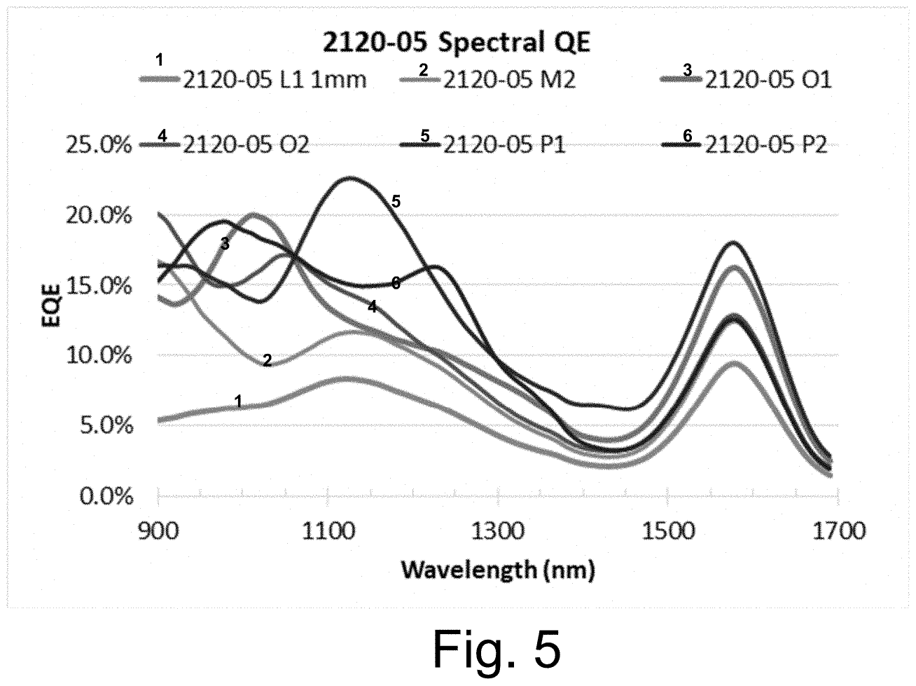

FIGS. 3A through 3C and FIG. 4 are scanning electron microscope (SEM) images of examples of optical grating couplers used to build Colloidal Quantum Dot (CQD) photodetectors in accordance with some embodiments of the present inventive concept. The structures shown in FIGS. 3A through 4, were fabricated to demonstrate the performance advantage of the present inventive concept. These structure are metal structures that correspond to FIG. 2, layer 200. Completed CQD photosensors were produced using these grating coupler structures and their spectral quantum efficiency performance was compared to CQD photosensors that did not contain an integrated optical grating couple. This data is shown in, for example, FIG. 5. Other examples of optical grating couplers utilize different shapes of period structures. These alternate grating shapes will be familiar to those skilled in the art. These structures include posts, pillars, holes, grids, recessed grids, combinations thereof and others. Embodiments of the present inventive concept use grating couplers in conjunction with CQD photodetectors to increase the optical quantum efficiency of CQD photodetectors without increasing the dark noise as compared to CQD photodetectors fabricated without an integrated optical grating structure.

FIG. 5 is a graph illustrating external quantum efficiency (EQE) versus wavelength (nm) for a plurality of different optical grating structures in accordance with some embodiments of the present inventive concept. In particular, FIG. 5 illustrates Spectral QE collected from five different optical grating structures on a specific device (2120-05). The L1 1 mm (1) does not incorporate an optical grating structure. All of these photodetectors were fabricated together on a same or similar substrate and all contain the same amount of CQD semiconductor material and all of the detectors had similar levels of dark current. It is clear from FIG. 5 that at a wavelength of 1550 nm, for example, the CQD photodetector with an optical grating structure (Labelled curve 5 in FIG. 5) had a quantum efficiency of approximately 18% and a CQD photodetector without an optical grating structure (Labelled curve 1 in FIG. 5) had a quantum efficiency of approximately 9%. This data demonstrates that the combination of an optical grating structure with a CQD photodetector provides a substantial increase in CQD detector performance over that without a grating structure.

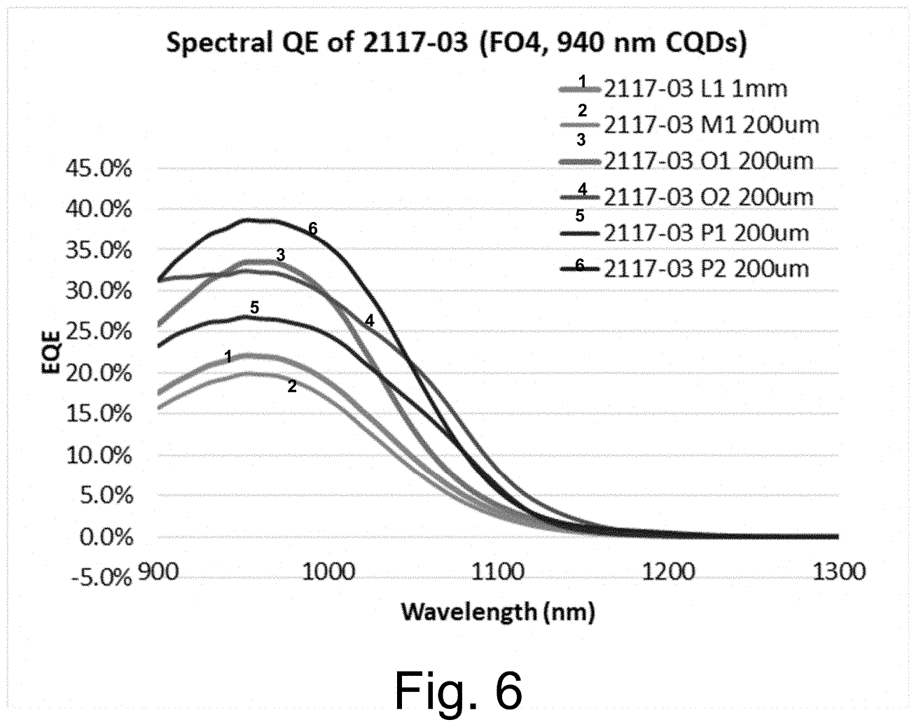

FIG. 6 is a graph illustrating EQE versus wavelength (nm) for a plurality of different optical grating structures in accordance with some embodiments of the present inventive concept. Spectral QE collected from five different optical grating structures on a specific device (2117-03). This device (2117-03) was fabricated with CQDs with a first excitonic transition of approximately 940 nm. 2117-03 L1 1 mm does not incorporate an optical grating structure. As illustrated in FIG. 6, structure P2 (6) has the highest QE at 940 nm (as compared to other structures). This corresponds with findings from device 2120-05 discussed with respect to FIG. 5.

The photodetectors whose spectral response is shown in FIG. 6 all have similar levels of dark current and dark noise. The data shown in FIG. 6 demonstrates that a CQD photodetector with an integrated optical grating coupler can provide QE enhancement and performance benefits for CQDs with a range of optical bandgaps.

As briefly discussed above, some embodiments of the present inventive concept provide grating couplers for use with non-QWIP focal plane array (FPA) sensor materials resulting in enhanced dark current to QE ratio.

Embodiments of the present inventive concept are described herein with reference to cross-section illustrations that are schematic illustrations of idealized embodiments of the present inventive concept. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present inventive concept.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Furthermore, although various layers, sections and regions of the photodetector may be discussed as being p-type and/or n-type, it is understood by those of skill in the art that in many devices these conductivity types may be switched without effecting the functionality of the device. If an element, region or layer is referred to as “n- type” this means that the element, layer or region has been doped to a certain concentration with n-type dopants, for example, Si, Germanium (Ge) or Oxygen. If an element region or layer is referred to “p-type” this means that the element, region or layer has been doped with p-type dopants, for example, magnesium (Mg), Beryllium (Be), Zinc (Zn), Calcium (Ca) or Carbon (C). In some embodiments, an element, region or layer may be discussed as “p⁺” or “n⁺,” which refers to a p-type or n-type element, region or layer having a higher doping concentration than the other p-type or n-type elements, regions or layers in the device. Finally, regions may be discussed as being epitaxial regions, implanted regions and the like. Although these regions may include the same material, the layer resulting from the various methods of formation may produce regions with different properties. In other words, an epitaxial grown region may have different properties than an implanted or deposited region of the same material.

As discussed above, embodiments of the present inventive concept provide grating couplers for use with non-QWIP focal plane array (FPA) sensor materials resulting in enhanced dark current to QE ratio. The design of grating coupler photodiode structures in accordance with some embodiments of the present inventive concept is based on an analytical analysis, and is optimized using empirical results, measured CQD film charge transport properties, and the requirements of scalable fabrication techniques.

The CQD layer or layers, or other photon-absorbing semiconductor layers (contained within, for example, layers 220 and 720) is not designed to maximize optical absorption but instead is optimized based on charge transport properties of the semiconductor material. Furthermore, the integrated grating structured discussed herein does not require sidewalls or sidewall reflection and instead is built to be continuous across the optically active region of the sensor. This optical grating structure does not require the fabrication of a resonant cavity in order the achieve the performance enhancement.

Thus, some embodiments of the present inventive concept provide a CQD detector with integrated grating coupler where the absorber material of the CQD layer or layers is continuous in the photoactive region, the structure has no sidewalls and there is no pixilation of optical grating structure. The grating coupler operates without reflected resonance and the structure is designed to optimized for CQD optical absorber layer thickness in the range of from about 50 to about 200 nm.

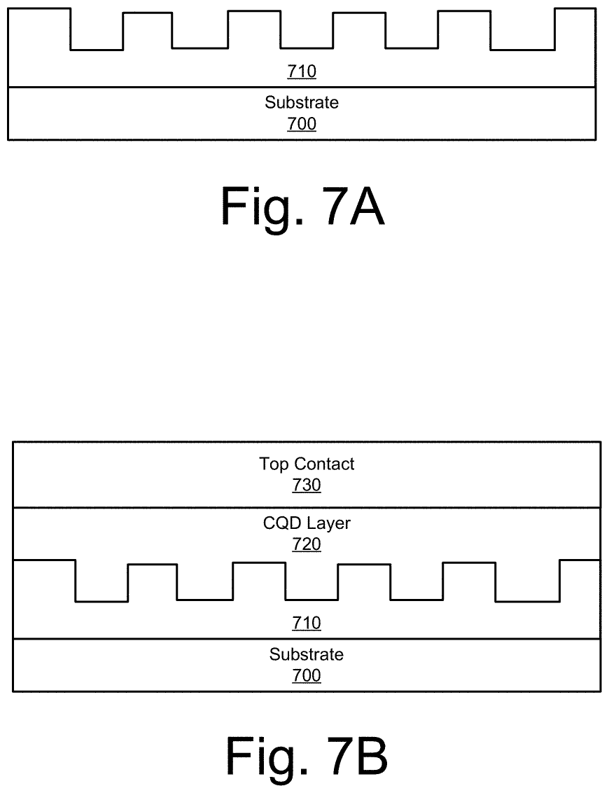

Referring now to the cross-sections of FIGS. 7A through 7B, processing steps in the fabrication of a photodetector including an optical grating coupler in accordance with some embodiments of the present inventive concept will be discussed. It will be understood that these figures only illustrate some embodiments of the methods in accordance with embodiments discussed herein and, therefore, embodiments of the present inventive concept is not limited to this configuration.

Referring first to FIG. 7A, a grating coupler structure 710 is formed on substrate 700. As discussed above, the substrate may be, for example, Si, Glass, Polymer, Ceramic, or metal material without departing from the scope of the present inventive concept. In some embodiments, the substrate may be a silicon (Si) IC wafer. The grating structure 710 discussed herein may be non-pixelated and does not contain sidewalls. However, it will be understood that the grating structure may be pixelated and/or contain sidewalls in some embodiments without departing from the present inventive concept.

In particular, to form the grating coupler structure 710, an oxide/dielectric material may be provided on the substrate 700. In some embodiments the oxide/dielectric material may be deposited on the substrate 700, however, embodiments of the present inventive concept are not limited to this configuration. For example, in some embodiments, the oxide/dielectric layer may be grown on the substrate 700. Once the oxide/dielectric layer is formed on the substrate 700, the oxide/dielectric layer may be patterned using, for example, ultraviolet (UV) lithography. A dry or wet etching process may then be used to form, for example, a continuous pattern of periodic structures as shown in FIG. 7A. As discussed above, this pattern is not limited to the periodic structure shown in FIG. 7A, random structures may also be used without departing from the scope of the present inventive concept. Once the patterning is complete, pixel pads, for example, metal pixel pads, may be deposited and patterned on the patterned oxide/dielectric to complete the grating coupler structure 710. In some embodiments, un-patterned pixel metal may be deposited on the planar oxide and then the material may be etched into the grating structure using, for example, UV lithography and a dry or wet etching process.

Although not shown in FIG. 7A, in some embodiments an optional charge transport layer may be deposited on the structure shown in FIG. 7A. This optional charge transport layer may be deposited across a sensor or wafer surface using, for example, spin coating, spray coating, dip coating, blade casting, and/or physical vapor deposition techniques.

Referring now to FIG. 7B, a continuous layer of CQDs 720 may be deposited on the structure of FIG. 7A using, for example, spin coating, spray coating, dip coating, or blade casting. In some embodiments, a CQD layer thickness controller may be used to keep the thickness of the CQD layer less than about 150 nm. The specific thickness may be selected to be the nominal charge transport distance within the CQD thin film. The CQD layer may or may not contain sidewalls within the active region of the photodiode structure.

In particular, a continuous layer of n-type or p-type CQDs or fullerene may be deposited on the structure of FIG. 7A to form a pn junction between the CQD layer 720 and the previous layer (layer 710). As used herein, the term “fullerene” refers to the buckminsterfullerene Cₙ as well as other forms of molecular carbon, such as C₇₀, C₈₄, and similar cage-like carbon structures, and more generally may range from 20 to several hundreds of carbon atoms, i.e., Cₙ where n is 20 or greater. The fullerene may be functionalized or chemically modified as desired for a specific purpose such as, for example, improving solubility or dispersability or modifying the electrical properties of the fullerene. The term “fullerene” may also refer to endohedral fullerenes wherein a non-carbon atom or atomic cluster is enclosed in the carbon cage. The term “fullerene” may also refer to fullerene derivatives. A few non-limiting examples of fullerene derivatives are [6,6]-phenyl-C₆₁-butyric acid methyl ester (PCBM) and phenyl-C₆₁-butyric acid cholestryl ester (PCBCR). The term “fullerene” may also refer to blends of the previously mentioned forms of fullerenes.

In a p-type semiconductor/CQD, the majority carriers are holes, and the minority carriers are electrons. In an n-type semiconductor/CQD, electrons are majority carriers, and holes are minority carriers. Semiconductors like germanium or silicon doped with any of the trivalent atoms like boron, indium or gallium may be p-type semiconductors. Phosphorus, arsenic, antimony, bismuth and the like are used to produce n-type semiconductors. As used herein, a “p-n junction” refers to an interface or a boundary between two semiconductor material types, namely the p-type and the n-type, inside a semiconductor. The thickness of the CQD layer 720 may be less than 150 nm in some embodiments.

Although not shown in FIG. 7B, an optional charge transport layer may be provided on the CQD layer 720. A top contact material 720, for example, Indium Tin Oxide (ITO) or Alluminum Zinc Oxide (AZO), may be provided on the complete diode stack, for example, on the CQD layer 720 or the optional charge transport layer. Other Examples of the electrode 720 include, but are not limited to, transparent conductive oxides (TCOs), transparent metals, and transparent conductive polymers. TCOs may include, for example, tin oxide (TO), indium tin oxide (ITO), zinc oxide (ZnO), zinc indium oxide (ZIO), zinc indium tin oxide (ZITO), gallium indium oxide (GIO), and further alloys or derivatives of the foregoing. Tin oxide may also be doped with fluorine (F). ZnO may be doped with a Group III element such as gallium (Ga), and/or aluminum (Al), and thus may be more generally stoichiometrically expressed as Znₓ Al_{y} Ga_{z}O where x+y+z=1, 0≤x≤1, 0≤y≤1, and 0≤z≤1. Other metal oxides may be suitable, as well as non-oxide thin-film semiconductors. In the case of metals, various metals (e.g., silver, gold, platinum, titanium, lithium, aluminum, magnesium, copper, nickel, and others), metal-inclusive alloys (including multi-layers or two or more different metals, with or without an adhesion-promoting layer such as tungsten), or metal-inclusive compounds may be employed as the electrode 720, so long as the metallic electrode 720 is thin enough to be transparent, i.e., has a “transparent thickness.” If the photodiode is desired to be sensitive in the IR range, then the electrode 720 should be sufficiently transparent to IR wavelengths. The electrode 720 is typically fabricated on the underlying surface by a vacuum deposition technique such as, for example, chemical vapor deposition (CVD), metalorganic CVD (MOCVD), radio-frequency (RF) or magnetron sputtering, molecular beam epitaxy (MBE), ion beam epitaxy, laser MBE, pulsed laser deposition (PLD), or the like. Depending on the composition, other deposition techniques such as thermal evaporation or sublimation may be suitable. A conductive polymer if sufficiently transparent may alternatively be employed as the electrode 720, and may be deposited by a solution-based process, spin coating, dip coating, spray coating, etc. One non-limiting example of a transparent conductive polymer is poly (3,4-ethylenedioxythiophene):polystryenesulfonate (PEDOT:PSS) and its chemical relatives and derivatives. Encapsulation layers may then be deposited to complete the structure.

As discussed above, FIGS. 7A and 7B are provide for example only. Layers may be positioned differently in the stack and/or additional layers may be present without departing from the scope of the present inventive concept.

In the drawings and specification, there have been disclosed exemplary embodiments of the inventive concept. However, many variations and modifications can be made to these embodiments without substantially departing from the principles of the present inventive concept. Accordingly, although specific terms are used, they are used in a generic and descriptive sense only and not for purposes of limitation, the scope of the inventive concept being defined by the following claims.

What is claimed is:

1. A non-quantum well infrared photodetector (QWIP) device, the device comprising an integrated optical grating coupler therein.

2. The device of claim 1, wherein the integrated optical grating coupler is positioned on a top surface of the device, a bottom surface of the device or in between the top surface and the bottom surface of the device in a middle portion of the device.

3. The device of claim 1, wherein the optical grating coupler includes a conductive material.

4. The device of claim 3, wherein the optical grating coupler comprises metal.

5. The device of claim 4, wherein the metal optical grating coupler comprises a patterned array of posts.

6. The device of claim 1, wherein a shape of the integrated optical grating coupler is periodic, random, post shaped, pillar shaped, contains holes, includes grids, and/or includes recessed grids.

7. The device of claim 1, wherein the non-QWIP device comprises a colloidal quantum dot (CQD) photodetector device.

8. The device of claim 1, wherein the device including the integrated optical grating coupler has an increased optical quantum efficiency without increasing dark noise relative to devices without integrated optical couplers.

9. The device of claim 8, wherein the quantum efficiency increases in devices having an integrated optical coupler by at least fifty percent.

10. The device of claim 1, wherein the integrated optical grating coupler is for use with wavelengths from about 800 nm to about 2500 nm.

11. The device of claim 1, wherein the device comprises non-QWIP materials that couple light at normal incidence.

12. The device of claim 11, wherein the non-QWIP materials comprise at least one of InGaAs, Si and CQD.

13. An integrated device comprising:
a substrate;
a CQD photodetector on the substrate; and
an integrated optical grating contact on the substrate.

14. The device of claim 13, wherein the integrated optical grating contact is a conductive grating contact and is provided between the substrate and the photodetector, the integrated device further comprising a top contact on the photodetector.

15. The device of claim 14, wherein the conductive grating contact is patterned to provide one of a periodic pattern and a random pattern.

16. The device of claim 14, wherein the conductive grating contact comprises a patterned array of posts.

17. The device of claim 13, where the device is a non-QWIP device.

18. The device of claim 17, wherein the device comprises non-QWIP materials that couple light at normal incidence.

19. The device of claim 18, wherein the non-QWIP materials comprise at least one of InGaAs, Si and CQD.

20. The device of claim 13, wherein presence of the integrated optical grating contact increases optical path length and optical absorption inside the photodetector.
